(19) United States
(12) Patent Application Publication
(10) Pub. No.: US 2005/0028739 A1
(43) Pub. Date: Feb. 10, 2005

(54) Semiconductor Manufacturing Apparatus

(75) Inventors: Masuhiro Natsuhara, Itami-shi, Hyogo (JP); Hirohiko Nakata, Itami-shi, Hyogo (JP)

Correspondence Address: JUDGE PATENT FIRM;RIVIERE SHUKUGAWA 3RD FL., 3-1 WAKAMATSU-CHO, NISHINOMIYA-SHI, HYOGO, 662-0035, JP

(73) Assignee: SUMITOMO ELECTRIC INDUSTRIES, LTD., Osaka-shi (JP)

(21) Appl. No.: 10/710,841

(22) Filed: Aug. 6, 2004

(30) Foreign Application Priority Data
Aug. 8, 2003 (JP) JP-2003-206806

(51) Int. Cl. C23C 16/00

(52) U.S. Cl. 118/728

(57) ABSTRACT

According to the present invention, a wafer holder is supported by support pieces mounted on a pedestal and is installed within the processing chamber of a semiconductor manufacturing device, wherein the lift pins are set up anchored to the semiconductor-manufacturing-device chamber and the pedestal is driven vertically, thereby running the wafer holder up/down to thrust the lift pins out from, or retract them into, the top side of the wafer holder, which makes it possible to dechuck wafers from and pocket them into the holder. Consequently, leveling the height of the tip ends of the plurality of lift pins is facilitated and synchronization problems are completely eliminated besides, which thus makes it possible to prevent wafer drop-off during wafer dechucking/pocketing. And since a mechanism for synchronously driving the plural lift pins up/down is unnecessary, the device overall can be made more compact.

### BACKGROUND OF INVENTION

1. Field of the Invention

The present invention relates to semiconductor manufacturing apparatus such as devices for plasma CVD devices, low-pressure CVD, metal CVD, dielectric CVD, ion-implantation, etching, low-k deposition, and degassing.

2. Background Art

Conventionally, in semiconductor manufacturing procedures various processes, such as film deposition and etching, are carried out on semiconductor substrates that are the processed objects. Wafer holders (ceramic susceptors) serving to retain semiconductor substrates and to heat the semiconductor substrates are used in the processing devices in which such processes on semiconductor substrates are carried out.

Japanese Unexamined Pat. App. Pub. No. H04-78138 for example discloses a conventional ceramic susceptor of this sort. The ceramic susceptor disclosed in H04-78138 includes, as shown in FIG. 3: a heater part 1 made of ceramic—into which a resistive heating element 2 is embedded and that is provided with a wafer-heating surface—arranged within a processing chamber 10; a columnar support part 7 that is provided on the side other than the wafer-heating side of the heater part 1, and that forms a gastight seal between it and the processing chamber 10; and electrodes 4 connected to the resistive heating element 2 and leading outside the processing chamber 10 so as essentially not to be exposed to the chamber interior space.

In another example, a structure in which retaining members that retain a ceramic susceptor, and in which electrodes for supplying electricity to the susceptor are surrounded by an inorganic insulating material is proposed in Japanese Unexamined Pat. App. Pub. No. H05-9740.

A problem with these structures, however, has been that because not only the ceramic susceptor, but also the columnar support part or the retaining members are installed in the processing chamber interior, the volume of the chamber is made large. Another problem has involved the plurality of lift pins that is generally furnished in a wafer holder in order to dechuck a wafer loaded onto the holder. To dechuck a wafer, the plurality of lift pins must be vertically driven synchronously, and if the synchronization timing is off, the wafer will tilt and can fall off and break.

Yet another problem with these structures has been that a mechanism that synchronizes and drives the plurality of lift pins up and down has to be installed, which makes the overall volume of the apparatus that much larger.

### SUMMARY OF INVENTION

The present invention has been brought about to resolve the foregoing problems. In particular, an object of the present invention is to make available semiconductor manufacturing apparatus in which, inasmuch as installing a mechanism for vertically driving the plurality of lifting pins synchronously is unnecessary, the volume of the apparatus overall can be made that much smaller, and inasmuch as synchronization of the plurality of lift pins need not be adopted, breakage due to wafer drop-off is completely eliminated.

The present invention is characterized in that a wafer holder for semiconductor manufacturing apparatus is supported by support pieces mounted on a pedestal and is set up within the processing chamber of a semiconductor manufacturing device, and is characterized in that a hermetic seal is formed between the pedestal and the chamber. It is desirable that the pedestal be vertically movable. It is likewise desirable that the hermetic seal between the pedestal and the processing chamber be formed by bellows.

The present invention is further characterized in that a plurality of through-holes through which lift pins pass is provided in a wafer holder for semiconductor manufacturing apparatus, wherein the wafer holder is configured so that it can be worked up/down to dechuck/pocket a wafer on the wafer holder.

The wafer holder is supported by the support pieces mounted on the pedestal and is installed within the processing chamber of a semiconductor manufacturing device, wherein the lift pins are set up anchored to the semiconductor-manufacturing-device chamber and the pedestal is driven vertically, thereby running the wafer holder up/down to thrust the lift pins out from, or retract them into, the top side (wafer-retaining face) of the wafer holder, which makes it possible to dechuck wafers from and pocket them into the holder.

Installing the plurality of lift pins anchored to the processing chamber facilitates leveling the height of the tip ends (wafer-supporting portions) of the plurality of lift pins and completely eliminates synchronization problems besides. And since a mechanism for synchronously driving the plural lift pins up/down is rendered unnecessary, the volume of the device overall can be made smaller.

From the following detailed description in conjunction with the accompanying drawings, the foregoing and other objects, features, aspects and advantages of the present invention will become readily apparent to those skilled in the art.

### BRIEF DESCRIPTION OF DRAWINGS

FIG. 1 illustrates one example of the cross-sectional structure of a semiconductor manufacturing device of the present invention;

FIG. 2 illustrates one example of the cross-sectional structure of another semiconductor manufacturing device of the present invention;

FIG. 3 illustrates one example of the cross-sectional structure of a conventional semiconductor manufacturing device;

FIG. 4 illustrates one example of the cross-sectional structure of an electrode for a semiconductor manufacturing device of the present invention; and

FIG. 5 illustrates one example of another cross-sectional structure of an electrode for a semiconductor manufacturing device of the present invention.

### DETAILED DESCRIPTION

In accordance with the present invention, a wafer holder for semiconductor manufacturing apparatus is supported by support pieces mounted on a pedestal and is set up within the processing chamber of a semiconductor manufacturing device, and a hermetic seal is formed between the pedestal and the chamber. In a preferred aspect of the invention the pedestal is vertically movable. Lending the wafer holder such a construction allows it to be driven up and down without ambient gases external to the processing chamber invading the chamber.

In another preferred aspect, the seal between the pedestal and the processing chamber is formed by bellows in order to realize smooth up-and-down movement of the pedestal and to barricade the interior/exterior atmospheres. Although the substance of the bellows is not particularly limited, from heat-resistance and corrosion-resistance perspectives, metals such as nickel, stainless steel, or aluminum are advisable.

Both the interval between the pedestal and the bellows, and between the bellows and the processing chamber are hermetically sealed, and while the sealing method is not particularly limited, publicly known techniques such as seals employing brazing or O-rings can be utilized.

In another aspect, a wafer holder utilized in the present invention is furnished with a plurality of through-holes through which lift pins penetrate, and aligned with the through-holes, a plurality of lift pins is installed within the processing chamber. The lift pins are anchored into the chamber. This eliminates the necessity of furnishing a mechanism for synchronously driving the plurality of lift pins. Thus a semiconductor manufacturing device according to the present invention can be scaled down smaller than conventional apparatus having such a drive mechanism.

The locations of the tips of the lift pins anchored within the processing chamber, in other words, the pins' topography of contact with a wafer, must be made uniplanar. The danger if this is not the case is that when the pins are supporting a wafer, the wafer might tilt and fall off. Nevertheless, because the lift pins in the present invention are not driven up and down as has been traditional but are fixed within the chamber, compared with the situation to date, adjustment of the tip locations is far easier.

The planarity of an imaginary surface formed by the tip-end faces of the plural lift pins preferably is 0.5 mm or less. A planarity that exceeds 0.5 mm raises the likelihood of wafer drop-off.

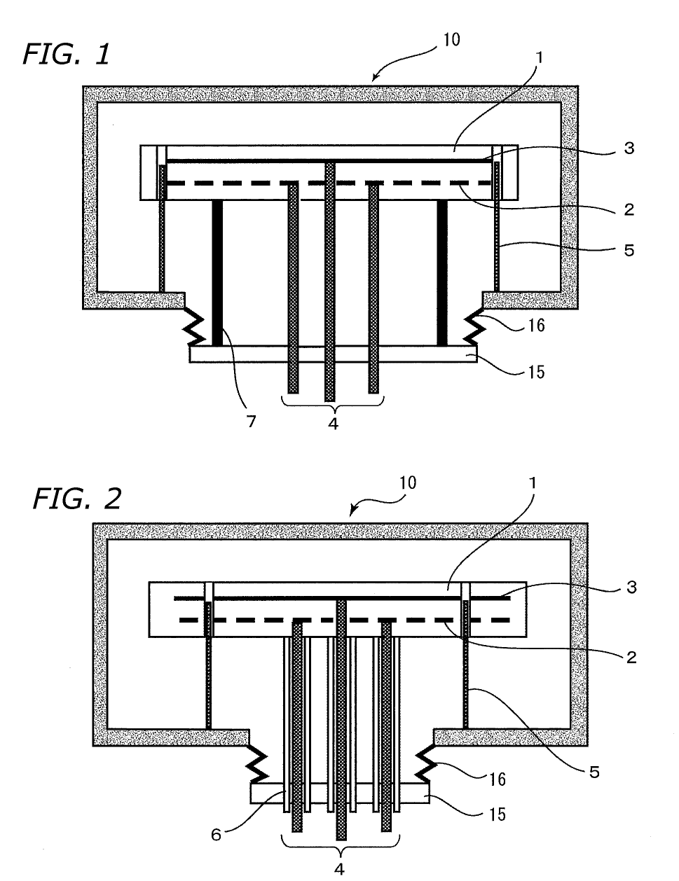

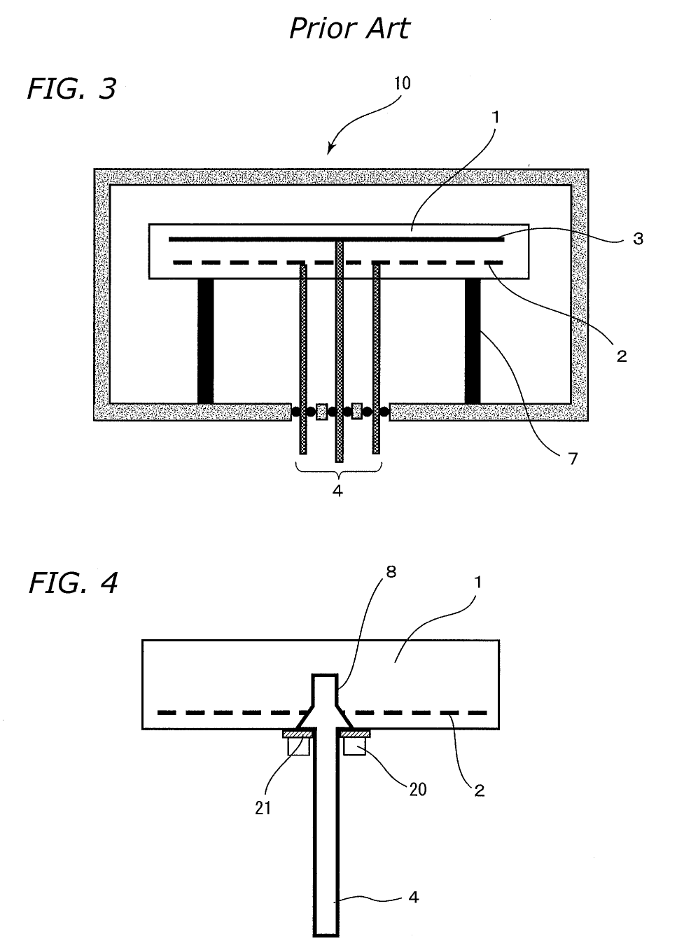

Reference is made to FIG. 1, wherein, as set forth above, the plurality of lift pins 5 is set up fixedly in the processing chamber 10 interior. Within the chamber of the semiconductor manufacturing device, the wafer holder 1 is set in place supported by the support pieces 7, which are mounted on the pedestal 15. Driving the pedestal up/down drives the wafer holder up/down to poke the lift pins out from, or retract them into, the top side (wafer-retaining face) of the wafer holder, whereby wafers can be dechucked from and pocketed into the holder.

Electroconductive elements including a resistive-heating-element circuit 2 and an RF-power generating circuit 3 are formed in the interior of and/or on the face of the wafer holder. Electrodes 4 for supplying electricity to these electroconductive elements are attached to the wafer holder. As indicated in FIG. 2, the electrodes can be made the support pieces. Thus rendering the configuration makes it possible to omit the support pieces 7, which structurally reduces the number of parts and monetarily lowers the cost.

The electrodes are preferably virgate in form. The cross-sectional geometry of the electrodes may be round, or may be polygonal—quadrilateral, triangular, etc.—but in order to prevent electric discharge from the electrodes to surrounding components in applications employing high voltage, a circular form is to be preferred.

There are no particular restrictions on the substance of the electrodes as long as the thermal expansion coefficient of the substance is close to the thermal expansion coefficient of the susceptor ceramic. For example, if the ceramic is a substance whose thermal expansion coefficient is comparatively small—such as aluminum nitride, silicon nitride, or silicon carbide—then tungsten, molybdenum, or tantalum is preferably utilized for the electrodes.

Especially in applications in which aluminum nitride—which, owing to its superlative corrosion resistance and other properties, in recent years has been increasingly utilized in susceptors for semiconductor manufacturing apparatus—is the ceramic, tungsten and molybdenum are particularly preferable electrode substances.

Furthermore, iron-nickel-cobalt alloys, whose thermal expansion coefficient can be matched to the thermal expansion coefficient of the susceptor ceramic, are utilizable for the electrodes. However, since the thermal expansion coefficient of iron-nickel-cobalt alloys changes abruptly depending on the temperature, whether to employ the alloys will necessarily depend on the use and the working temperature.

A further consideration with regard to the electrode substance is that if the ceramic is aluminum oxide (alumina), because its thermal expansion coefficient is larger than that of the ceramics mentioned above, a wide variety of iron-nickel-cobalt alloys would be utilizable in addition to the foregoing electrode materials.

The electrodes can according to need also be subjected to a surface treatment and coated with a protective film. More specifically, if the electrodes are to be protected from an oxidizing atmosphere the surface of the electrodes preferably is plated with nickel, gold, or silver. The electrodes can also be multi-plated with these metals. For example, plating the electrodes initially with nickel, and then plating gold or silver onto the nickel plating will further improve the electrodes' resistance to corrosion. The kind and combination of platings can be appropriately selected in accordance with the application, that is, with the temperature and atmosphere in which the electrodes are used.

Optionally, a flame-spray coating can be formed on the surface of the electrodes. For example, flame-spraying alumina or mullite onto the electrodes' surface contributes to improving their corrosion resistance against operational gases such as oxygen. As a further example, an aluminum nitride coating can be formed on the surface of the electrodes by flame-spraying them with aluminum within a nitrogen atmosphere. Inasmuch as the ability of aluminum nitride to withstand corrosion is particularly outstanding, the coating is especially effective in improving the electrodes' corrosion resistance.

Nevertheless, if a ceramic such as that just mentioned is to be flame-sprayed onto the electrodes, then it is necessary that the portion of the electrodes that is electrically connected with the electroconductive elements formed in the interior and/or on the surface of the ceramic susceptor not be flame-sprayed with the coating ceramic. The reason for this is that inasmuch as the coating ceramic is an insulator, if even the portion of the electrodes for electrical connection were flame-sprayed, then an electrical connection could not be established. Apart from the coating ceramic, another material with which the electrodes can be flame-sprayed is a metal such as nickel, gold, or silver.

Likewise, apart from plating and flame-spraying, thin-film forming techniques of all kinds, such as ion plating, CVD, sputtering, and vacuum evaporation, can be adopted as ways of forming the foregoing protective coating. The type of protective film and the method of its formation can be chosen to suit, according to the various applications.

Next, methods according to the present invention of electrically connecting the foregoing electrodes with the electroconductive elements formed in the interior and/or on the surface of the ceramic susceptor will be explained. Reference is made to FIG. 4, in which from within a ceramic susceptor 1, an electroconductive element 2 formed in the susceptor is exposed. The fore end 8 of an electrode 4 is male-screw threaded, and the susceptor is female-screw tapped; screwing the electrode 4 into the ceramic susceptor 1 to directly contact the electrode with the electroconductive element enables a stabilized electrical connection to be achieved.

Chamfering the exposed area of the susceptor 1 into a countersink further stabilizes the electrical connection in this configuration. In addition, forming a metal film on the countersink by a metallization process augments the contact surface area of the electrical connection, which improves the reliability of the electrical connection. As a separate method for doing so, inserting metal foil into the countersink similarly enables the contact surface area to be increased. Although the metal foil that is inserted may be the same substance as that of the electrode, with the objective of both increasing the surface area and reducing the contact resistance, soft metals such as gold and silver as well as copper and aluminum are preferable.

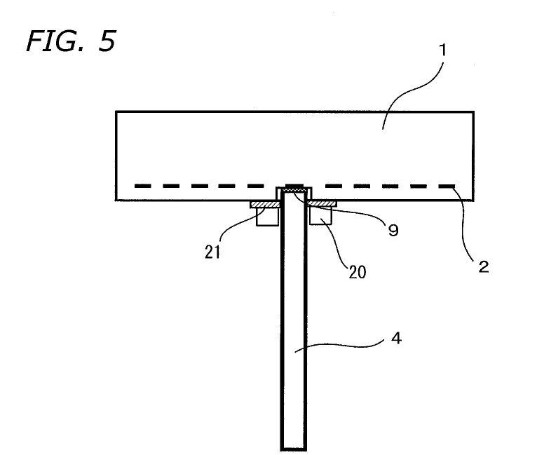

Another connection method that is possible is, as illustrated in FIG. 5, to braze the electrode 4 to the electroconductive element 2 employing a brazing fillet 9. A silver brazing material or an active metal brazing material can be employed as the brazing fillet. Although in this way the electrode and the electroconductive element are electrically connected, the corrosion resistance in the connecting region suffers, and thus it is preferable that, utilizing a ceramic member 20 as depicted in FIG. 4, the connection be sealed by means of glass 21. Sealing the connection in this way stops oxygen and reaction gases from invading the connection region and thus further improves the reliability of the connection.

In a further aspect of the present invention, as illustrated in FIG. 2, a tubular piece 6 can be installed encompassing each electrode 4. With the role of the tubular pieces 6 being to prevent shorting between the plural electrodes, installing the pieces is to be preferred in order to enhance the electrodes' reliability. It is especially advantageous to install tubular pieces in instances in which between electrodes the separation is short and the difference in electric potential is large. The tubular pieces 6 are preferably of an insulative material that is heat-resistant.

Another feasible configuration according to the present invention is to isolate the space inside the tubular pieces from the atmosphere inside the processing chamber of the semiconductor manufacturing equipment. Isolating the tubular-piece interior space makes the prevention of inter-electrode shorting the more reliable and completely eliminates exposure of the electrodes to corrosive gases, thus further enhancing the durability of the electrodes. One isolation method is for example a technique in which the tubular pieces are joined to the ceramic susceptor with glass or an active metal brazing material, and the interval in between the tubular pieces and the pedestal is hermitically sealed with an O-ring. The substance of which the tubular pieces is made—inasmuch as they are joined to the ceramic susceptor—preferably is the same as the susceptor ceramic, or is a substance whose difference in thermal expansion coefficient with the susceptor ceramic is 5×10⁻⁶/° C. or less.

Thus fitting the electrodes with the tubular pieces is advantageous because even in employing the wafer holder under high voltage it eliminates electrical discharge between the electrodes themselves and between the electrodes and the processing chamber, as well as between the electrodes and the pedestal. If the pedestal is to be of an electroconductive material such as metal, then inserting insulating stuff such as ceramic in between where the O-ring and the pedestal would touch serves to prevent shorting the more reliably.

Although the substantive material of a wafer holder in the present invention is not particularly limited as long as the material is an insulative ceramic, aluminum nitride (AlN), being highly thermoconductive and superlative in corrosion resistance, is preferable. In the following, a method according to the present invention of manufacturing a wafer holder in the case of AlN will be detailed.

AlN raw material powder whose specific surface area is 2.0 to 5.0 m²/g is preferable. The sinterability of the aluminum nitride declines if the specific surface area is less than 2.0 m²/g. Handling proves to be a problem if on the other hand the specific surface area is over 5.0 m²/g, because the powder coherence becomes extremely strong. Furthermore, the quantity of oxygen contained in the raw-material powder is preferably 2 wt. % or less. In sintered form, the thermal conductivity of the material is compromised if the oxygen quantity is in excess of 2 wt. %. It is also preferable that the amount of metal impurities other than aluminum contained in the raw-material powder be 2000 ppm or less. The thermal conductivity of a sintered compact of the powder is compromised if the amount of metal impurities exceeds this range. In particular, the content respectively of Group IV elements such as Si, and elements of the iron family, such as Fe, which as metal impurities have a serious worsening effect on the thermal conductivity of a sintered compact, is advisably 500 ppm or less.

Because AlN is not a readily sinterable material, adding a sintering promoter to the AlN raw-material powder is advisable. The sintering promoter added preferably is a rare-earth element compound. Since rare-earth element compounds during sintering react with aluminum oxides or aluminum oxynitrides present on the surface of the particles of the aluminum nitride powder, acting to promote densification of the aluminum nitride and to eliminate oxygen being a causative factor that worsens the thermal conductivity of the aluminum nitride sintered part, they enable the thermal conductivity of the aluminum nitride sintered part to be improved.

Yttrium compounds, whose oxygen-eliminating action is particularly pronounced, are preferable rare-earth element compounds. The amount added is preferably 0.01 to 5 wt. %. Less than 0.01 wt. % would rule out producing ultra-fine sintered materials, along with which the thermal conductivity of the sintered parts would be compromised. Added amounts in excess of 5 wt. % on the other hand lead to sintering promoter being present at the grain boundaries in the aluminum nitride sintered part, and consequently, if the compact is employed under a corrosive atmosphere, the sintering promoter present along the grain boundaries gets etched, becoming a source of loosened grains and particles. More preferably the amount of sintering promoter added is 1 wt. % or less. Being less than 1 wt. %, the sintering promoter will no longer be present even at the grain boundary triple points, which improves the corrosion resistance.

To characterize the rare-earth compounds further: oxides, nitrides, fluorides, and stearic oxide compounds may be employed. Among these, oxides, being inexpensive and readily obtainable, are preferable. By the same token, stearic oxide compounds are especially suitable since they have a high affinity for organic solvents, and if the aluminum nitride raw-material powder, sintering promoter, etc. are to be mixed together in an organic solvent, the fact that the sintering promoter is a stearic oxide compound will heighten the miscibility.

Next, a predetermined volume of solvent, a binder, and further, a dispersing agent or a coalescing agent as needed, are added to the aluminum nitride raw-material powder and powdered sintering promoter, and the mixture is blended together. Possible mixing techniques include ball-mill mixing and mixing by ultrasound. Mixing techniques of this sort allow a raw-material slurry to be produced.

The obtained slurry is molded, and the molded product is sintered to yield a sintered aluminum-nitride part. Co-firing and metallization are two possible methods as a way of doing this.

Metallization will be described first. Granules are prepared from the slurry by spray-drying it, or by means of a similar technique. The granules are inserted into a predetermined mold and subject to press-molding. The pressing pressure therein desirably is 0.1 t/cm² or more. With pressure less than 0.1 t/cm², sufficient strength in the molded part cannot be produced in most cases, making the piece liable to break in handling.

Although the density of the molded part will differ depending on the amount of binder contained and on the amount of sintering promoter added, the density is preferably 1.5 g/cm³ or more. A density of less than 1.5 g/cm³ would mean a relatively large distance between particles in the raw-material powder, which would hinder the progress of the sintering. At the same time, the molded product density preferably is 2.5 g/cm³ or less. Densities of more than 2.5 g/cm³ would rule out sufficiently eliminating the binder from within the molded product in the degreasing process of the ensuing manufacturing procedure. It would consequently prove difficult to produce an ultrafine sintered part as described earlier.

Next, the molded product is heated within a non-oxidizing atmosphere to put it through a degreasing process. Carrying out the degreasing process under an oxidizing atmosphere such as air would degrade the thermal conductivity of the sinter, because the AlN powder would become superficially oxidized. For the non-oxidizing ambient gases, nitrogen and argon are preferable. The heating temperature in the degreasing process is preferably 500° C. or more and 1000° C. or less. With temperatures of less than 500° C., carbon is left remaining in excess within the molded part following the degreasing process because the binder cannot sufficiently be eliminated, which interferes with sintering in the subsequent sintering procedure. On the other hand, at temperatures of more than 1000° C., the amount of carbon left remaining turns out to be too little, such that the ability to eliminate oxygen from the oxidized coating superficially present on the surface of the AlN powder is compromised, degrading the thermal conductivity of the sintered part.

Another condition is that the amount of carbon left remaining within the molded product after the degreasing process is preferably 1.0 wt. % or less. Since carbon remaining in excess of 1.0 wt. % interferes with sintering, an ultrafine sintered part cannot be produced.

Next, sintering is carried out. The sintering is carried out within a non-oxidizing nitrogen, argon, or like atmosphere, at a temperature of 1700 to 2000° C. Therein the moisture contained in the ambient gas, such as nitrogen, that is employed is preferably −30° C. or less given in dew point. If the atmosphere were to contain more moisture than this, the thermal conductivity of the sintered part would likely be compromised, because the AlN would react with the moisture within the ambient gas during sintering and form nitrides. Another preferable condition is that the volume of oxygen within the ambient gas be 0.001 vol. % or less. A larger volume of oxygen would lead to a likelihood of the AlN becoming superficially oxidized, impairing the thermal conductivity of the sintered part.

As another condition during sintering, the jig employed is suitably a boron-nitride (BN) molded article. Inasmuch as the jig as a BN molded article will be sufficiently heat resistant against the sintering temperatures, and superficially will have solid lubricity, friction between the jig and the molded part when the block contracts during sintering will be lessened, which will enable sinter products with little distortion to be produced.

The obtained sintered part is subjected to processing according to requirements. In cases where a conductive paste is to be screen-printed onto the sintered part in the ensuing manufacturing steps, the surface roughness is preferably 5 □m or less in Ra. If over 5 □m, in screen printing to form a circuit on the compact, defects such as blotting or pinholes in the pattern are liable to arise. More suitable is a surface roughness of 1 □m or less in Ra.

In polishing to the abovementioned surface roughness, although cases in which screen printing is done on both sides of the sintered part are a matter of course, even in cases where screen printing is effected on one side only, the polishing process should also be carried out on the surface on the side opposite the screen-printing face. This is because polishing only the screen-printing face would mean that during screen printing, the sintered part would be supported on the unpolished face, and in that situation burrs and debris would be present on the unpolished face, destabilizing the fixedness of the sintered part such that the circuit pattern might not be drawn well by the screen printing.

Furthermore, at this point the thickness uniformity (parallelism) between the processed faces is preferably 0.5 mm or less. Thickness uniformity exceeding 0.5 mm can lead to large fluctuations in the thickness of the conductive paste during screen printing. Particularly suitable is a thickness uniformity of 0.1 mm or less. Another preferable condition is that the planarity of the screen-printing face be 0.5 mm or less. If the planarity exceeds 0.5 mm, in that case too there can be large fluctuations in the thickness of the conductive paste during screen printing. Particularly suitable is a planarity of 0.1 mm or less.

Screen printing is used to spread a conductive paste and form the electrical circuits onto the sintered part having undergone the polishing process. The conductive paste can be obtained by mixing together with a metal powder an oxide powder, a binder, and a solvent according to requirements. The metal powder is preferably tungsten (W), molybdenum (Mo) or tantalum (Ta), since their thermal expansion coefficients match those of ceramics.

Adding the oxide powder to the conductive paste is also to enhance the strength with which it bonds to AlN. The oxide powder preferably is an oxide of Group IIA or Group IIIA elements, or is Al₂O₃, SiO₂, or a like oxide. Yttrium oxide is especially preferable because it has very good wettability with AlN. The amount of such oxides added is preferably 0.1 to 30 wt. %. If the amount is less than 0.1 wt. %, the bonding strength between AlN and the metal layer being the circuit that has been formed is compromised. On the other hand, amounts in excess of 30 wt. % elevate the electrical resistance of the metal layer that is the electrical circuit.

Another option with regard to the conductive paste is that the metal powder may be one whose chief component is a metal selected from silver, palladium, and platinum. In particular, silver-based metals such as Ag—Pd and Ag—Pt are preferable. Electrical resistance of the circuits formed with the paste in that case may be controlled by adjusting the amount of palladium (Pd) or platinum (Pt) that the Ag-based metal contains. Furthermore, the same oxide powders as in the case of the tungsten or other metal powders may be added to the Ag-based metal powders. In this case too, the oxide addition amount preferably is 1 wt. % or more and 30 wt. % or less.

These powders are mixed together, and by adding a binder and a solvent to the mixture a paste is prepared; predetermined circuit patterns are formed with the paste by screen printing. In doing so, the thickness of the conductive paste is preferably 5 □m or more and 100 □m or less in terms of its post-drying thickness. If the thickness is less than 5 □m the electrical resistance would be too high and the bonding strength would decline. Likewise, if in excess of 100 □m the bonding strength would be compromised in that case as well.

Also preferable is that in the patterns for the circuits that are formed, in the case of the heater circuit (resistive heating element circuit), the pattern spacing be 0.1 mm or more. With a spacing of less than 0.1 mm, shorting will occur when current flows in the resistive heating element and, depending on the applied voltage and the temperature, leakage current is generated. Particularly in cases where the circuit is employed at temperatures of 500° C. or more, the pattern spacing preferably should be 1 mm or more; more preferable still is that it be 3 mm or more.

After the conductive paste is degreased, baking follows. Degreasing is carried out within a non-oxidizing nitrogen, argon, or like atmosphere. The degreasing temperature is preferably 500° C. or more. At less than 500° C., elimination of the binder from the conductive paste is inadequate, leaving behind in the circuit metal layer carbon that when the circuit is baked on will form metal carbides and consequently raise the electrical resistance of the metal layer.

With conductive paste containing W, Mo or Ta, the baking is suitably done within a non-oxidizing nitrogen, argon, or like atmosphere at a temperature of 1500° C. or more. At temperatures of less than 1500° C., the post-baking electrical resistance of the metal layer turns out too high because the baking of the metal powder within the paste does not proceed to the grain growth stage. A further baking parameter is that the baking temperature should not surpass the sintering temperature of the ceramic produced. If the conductive paste is baked at a temperature beyond the sintering temperature of the ceramic, dispersive volatilization of the sintering promoter incorporated within the ceramic sets in, and moreover, grain growth in the metal powder within the conductive paste is accelerated, impairing the bonding strength between the ceramic and the metal layer.

In the case of Ag-based metals on the other hand, the baking temperature preferably is 700° C. to 1000° C. The baking may be done within an air or a nitrogen atmosphere. The degreasing process described above can be omitted in processing a circuit pattern printed with an above-described Ag-based conductive paste.

Next, in order to ensure that the formed metal layer is electrically isolated, an insulative coating can be formed on the metal layer. Preferably the insulative coating substance is the same substance as the ceramic on which the metal layer is formed. Problems such as post-sintering warpage arising from the difference in thermal expansion coefficients will occur if the ceramic and insulative coating substances differ significantly. For example, in a case where the ceramic is AlN, a predetermined amount of, as a sintering promoter, an oxide/carbide of a Group IIA element or a Group IIIA element can be added to and mixed together with AlN powder, a binder and a solvent added and the mixture rendered into a paste, and the paste can be screen-printed to spread it onto the metal layer.

In that instance, the amount of sintering promoter added preferably is 0.01 wt. % or more. With an amount less than 0.01 wt. % the insulative coating does not densify, which is prohibitive of ensuring electrical isolation of the metal layer. It is further preferable that the amount of sintering promoter not exceed 20 wt. %. Surpassing 20 wt. % leads to excess sintering promoter invading the metal layer, which can end up altering the metal-layer electrical resistance. Although not particularly limited, the spreading thickness preferably is 5 □m or more. This is because securing electrical isolation proves to be problematic at less than 5 □m.

Next, in the present method, the ceramic as substrates furthermore can be laminated according to requirements. Lamination may be done via an adhesive. The adhesive—being a compound of Group IIA or Group IIIA elements, and a binder and solvent, added to an aluminum oxide powder or aluminum nitride powder and made into a paste—is spread onto the joining surface by a technique such as screen printing. The thickness of the applied adhesive is not particularly restricted, but preferably is 5 □m or more. Joining defects such as pinholes and adhesive irregularities are liable to arise in the adhesive layer at thicknesses of less than 5 □m.

The ceramic substrates onto which the adhesive has been spread are degreased within a non-oxidizing atmosphere at a temperature of 500° C. or more. The ceramic substrates are thereafter joined to one another by stacking together ceramic substrates to be laminated, applying a predetermined load to the stack, and heating it within a non-oxidizing atmosphere. The load preferably is 5 kPa (0.05 kg/cm²) or more. With loads of less than 5 kPa sufficient joining strength will not be obtained, and otherwise the joining defects just noted will be prone to occur.

Although the heating temperature for joining is not particularly restricted as long as it is a temperature at which the ceramic substrates adequately bond to one another via the joining layers, preferably it is 1500° C. or more. With adequate joining strength proving difficult to gain at less than 1500° C., defects in joining are liable to arise. Nitrogen or argon is preferably employed for the non-oxidizing atmosphere during the degreasing and joining just discussed.

A ceramic sinter laminate that serves as a wafer holder can be produced as in the foregoing. As far as the electrical circuitry is concerned, it should be understood that if it is a heater circuit for example, then a molybdenum coil can be utilized, and in cases such as with electrostatic-chuck electrodes or RF electrodes, molybdenum or tungsten mesh can be, without employing conductive paste.

In such cases, the molybdenum coil or the mesh can be built into the AlN raw-material powder, and the ceramic heater-block can be fabricated by hot pressing. While the temperature and atmosphere in the hot press may be on par with the AlN sintering temperature and atmosphere, the hot press desirably applies a pressure of 1 MPa (10 kg/cm²) or more. With pressure of less than 1 MPa, the wafer holder might not demonstrate its performance capabilities, because cracks arise between the AlN and the molybdenum coil or the mesh.

Co-firing will now be explained. The earlier-described raw-material slurry is molded into sheets by doctor blading. The sheet-molding parameters are not particularly limited, but the post-drying thickness of the sheets advisably is 3 mm or less. The sheet thickness surpassing 3 mm leads to large shrinkage in the drying slurry, raising the probability that fissures will be generated in the sheet.

A metal layer of predetermined form that serves as an electrical circuit is formed onto an abovementioned sheet using a technique such as screen printing to spread onto it a conductive paste. The conductive paste utilized can be the same as that which was descried under the metallization method. Nevertheless, not adding an oxide powder to the conductive paste does not hinder the co-firing method.

Subsequently, the sheet that has undergone circuit form ation is laminated with sheets that have not. Lamination is by setting the sheets each into predetermined position to stack them together. Therein, according to requirements, a solvent is spread on between sheets. In the stacked state, the sheets are heated as may be necessary. In cases where the stack is heated, the heating temperature is preferably 150° C. or less. Heating to temperatures in excess of this greatly deforms the laminated sheets. Pressure is then applied to the stacked-together sheets to unitize them. The applied pressure is preferably within a range of from 1 to 100 MPa. At pressures less than 1 MPa, the sheets are not adequately unitized and can peel apart during subsequent manufacturing steps. Likewise, if pressure in excess of 100 MPa is applied, the extent to which the sheets deform becomes too great.

This laminate undergoes a degreasing process as well as sintering, in the same way as with the metallization method described earlier. Parameters such as the temperature in degreasing and sintering, and the amount of carbon are the same as with metallization. A wafer holder having plural electrical circuitry can be readily fabricated by printing, in the previously described screen printing of a conductive paste onto sheets, heater circuits, electrostatic-chuck electrodes, etc. respectively onto a plurality of sheets and laminating them. In this way a ceramic sinter laminate that serves as a wafer holder can be produced.

The obtained ceramic sinter laminate is subject to processing according to requirements. As a rule, in the sintered state the ceramic sinter laminate usually is not within the precision demanded in semiconductor manufacturing equipment. The planarity of the wafer-carrying side as an example of processing precision is preferably 0.5 mm or less; moreover 0.1 mm or less is particularly preferable. The planarity surpassing 0.5 mm is apt to give rise to breaches between the wafer holder and a wafer the holder carries, keeping the heat of the wafer holder from being uniformly transmitted to the wafer and making the generation of temperature irregularities in the wafer likely.

A further preferable condition is that the surface roughness of the wafer-carrying side be 5 □m in Ra. If the roughness is over 5 □m in Ra, grains loosened from the AlN due to friction between the wafer holder and the wafer can grow numerous. Grain-loosened particles in that case become contaminants that have a negative effect on processes, such as film deposition and etching, on the wafer. Furthermore, then, a surface roughness of 1 □m or less in Ra is ideal.

A base part for a wafer holder can thus be fabricated as in the foregoing. Following that, electrodes are attached to the wafer holder. The attachment can be carried out by one of the techniques described earlier. Thus a wafer holder for semiconductor manufacturing apparatus can be fabricated. A semiconductor manufacturing device of the present invention can be rendered by attaching the wafer holder to the pedestal via the support pieces and fitting the assembly into a semiconductor manufacturing device.

Embodiment

99.5 parts by weight aluminum nitride powder and 0.5 parts by weight Y₂O₃ powder were blended together; 10 parts by weight polyvinyl butyral as a binder and 5 parts by weight dibutyl phthalate as a solvent were added to the mixture, which was then mixed in a ball mill for 24 hours to prepare a slurry. Here, an aluminum nitride powder of 0.6 □m mean particle diameter and 3.4 m²/g specific surface area was utilized. The slurry was granulated by spray-drying, and the granules were charged into a mold and molded to produce a molded part. After being degreased at 800° C., the molded part was sintered 6 hours at 1850° C. to yield a sintered AlN part. Here, the ambient during degreasing and sintering was made a nitrogen atmosphere.

Furthermore, a tungsten paste was prepared by adding, to 100 parts by weight tungsten powder of 2.0 □m mean particle diameter, Y₂O₃ powder at 1 part by weight, Al₂O₃ at 0.6 weight %, and ethyl cellulose—a binder—and butyl Carbitol™ as a solvent, and mixing the ingredients together. A pot mill and a triple-roller mill were used for mixing. On the two sides of the foregoing sintered AlN part this tungsten paste was formed into, respectively, a heater circuit pattern and circular circuit pattern by screen-printing. The circular circuit pattern may be configured as a circuit for the generation of RF power, or a circuit for the irradiation of an electron beam (EB).

Tungsten electroconductive-element circuits were formed by degreasing within a nitrogen atmosphere at 800° C. the sintered AlN part on which the circuits just described were formed and thereafter baking the part 6 hours in a nitrogen atmosphere at 1800° C. In addition, a ceramic paste was prepared by adding a binder and an organic solvent to a powder composed of 20 parts by weight AlN, 30 parts by weight Y₂O₃, with the remainder being Al₂O₃. This ceramic paste was by screen-printing spread onto the two sides of the sintered AlN part on which the tungsten electroconductive-element circuits were formed, and after being dried the sintered AlN part thus coated was degreased within a nitrogen atmosphere at 800° C. A sintered AlN part on which tungsten electroconductive-element circuits were not formed was laminated onto each of the two sides of this sintered AlN part and the laminate was hot-pressed 2 hours under a pressure of 2 MPa within an 1800° C. nitrogen atmosphere, whereby a wafer holder was produced.

The wafer holder was spot-faced through the surface on the side opposite its wafer-retaining face, as far as the heater circuit pattern and as far as the circular circuit pattern, to expose a portion of each circuit. Then a threading operation was carried out on the spot-faced holes and electrodes were screwed into the holes, as indicated in FIG. 4. The electrodes were of tungsten manufacture, 3 mm in diameter, and had been nickel-plated.

The wafer holder into which the foregoing electrodes had been attached was mounted as represented in FIG. 1 on a pedestal 15 made of SUS steel, via cylindrical support pieces 7 also made of SUS steel. This assembly was installed in the processing-chamber 10 interior of a semiconductor manufacturing device, and with bellows made of nickel a hermetic seal was formed between the pedestal and the chamber. In this case, in 3 equidistantly spaced places in the wafer holder holes for penetration by the lift pins 5 were provided, wherein the wafer holder was set into place so that the lift pins 5 having been fixed to the chamber 10 would penetrate through the holes. The heights of the tip-end faces of the three lift pins were adjusted so that the height variance would be within 0.5 mm.

An Si wafer was loaded into the semiconductor manufacturing device assembled as in the foregoing, gaseous WF₆ as a reaction gas was introduced into the device, and the wafer was heated to 500° C.; and by applying high RF power at 13.56 MHz to the circular circuit pattern to generate a plasma, a tungsten film was deposited onto the wafer. The result was that an excellent tungsten film free of defects could be formed. What is more, in between the electrodes sparking or similar problems did not occur.

Then the wafer was dechucked/pocketed by working the pedestal up/down to poke the lift pins out of and retract them into the wafer holder. Although this dechucking/pocketing was repeated 1000 times, the wafer did not fall off the lift pins even once.

In contrast, using a conventional semiconductor manufacturing device in which the lift pins themselves are worked up/down, 1000 cycles of wafer dechucking/pocketing were likewise performed, wherein the wafer fell off the lift pins three times.

Compared with conventional semiconductor manufacturing apparatus, moreover, a semiconductor manufacturing device of the present invention does not require a mechanism to work the lift pins up/down synchronously, which enables the device overall to be made more compact.

According to the present invention as given in the foregoing, a wafer holder is supported by support pieces mounted on a pedestal and is installed within the processing chamber of a semiconductor manufacturing device, wherein the lift pins are set up anchored to the semiconductor-manufacturing-device chamber and the pedestal is driven vertically, thereby running the wafer holder up/down to thrust the lift pins out from, or retract them into, the top side (wafer-retaining face) of the wafer holder, which makes it possible to dechuck wafers from and pocket them into the holder.

Consequently, installing the plurality of lift pins anchored to the processing chamber facilitates leveling the height of the tip ends (wafer-supporting portions) of the plurality of lift pins and completely eliminates synchronization problems besides, therefore making it possible to prevent wafer drop-off during wafer dechucking/pocketing. And since a mechanism for synchronously driving the plural lift pins up/down is rendered unnecessary, the device overall can be made more compact.

Only selected embodiments have been chosen to illustrate the present invention. To those skilled in the art, however, it will be apparent from the foregoing disclosure that various changes and modifications can be made herein without departing from the scope of the invention as defined in the appended claims. Furthermore, the foregoing description of the embodiments according to the present invention is provided for illustration only, and not for limiting the invention as defined by the appended claims and their equivalents.

1. A semiconductor manufacturing device having a processing chamber, the semiconductor manufacturing device comprising:
a wafer holder set up within the processing chamber;
a pedestal;
support pieces mounted on said pedestal; and
a hermetic seal is formed between said pedestal and said chamber.

2. A semiconductor manufacturing device as set forth in claim 1, wherein said pedestal is vertically movable.

3. A semiconductor manufacturing device as set forth in claim 1, wherein said hermetic seal between said pedestal and the processing chamber is formed by bellows.

4. A semiconductor manufacturing device as set forth in claim 2, wherein said hermetic seal between said pedestal and the processing chamber is formed by bellows.

5. A semiconductor manufacturing device comprising:
a wafer holder provided with a plurality of through-holes through which lift pins pass, wherein said wafer holder is configured so that a wafer thereon can be dechucked/pocketed by working the wafer holder up/down.
